(19) United States
(12) Patent Application Publication
(10) Pub. No.: US 2023/0028288 A1
(43) Pub. Date: Jan. 26, 2023

(54) METHOD, DRIVE DEVICE, OPTICAL SYSTEM AND LITHOGRAPHY APPARATUS

(71) Applicant: Carl Zeiss SMT GmbH, Oberkochen (DE)

(72) Inventor: Sönke RHEIN, Nattheim (DE)

(21) Appl. No.: 17/958,661

(22) Filed: Oct. 3, 2022

Related U.S. Application Data
(63) Continuation of application No. PCT/EP2021/057258, filed on Mar. 22, 2021.

(30) Foreign Application Priority Data
Apr. 6, 2020 (DE) 102020204415.5

(51) Int. Cl. G03F 7/20

(52) U.S. Cl. CPC G03F 7/70258; G03F 7/705; G03F 7/70525; H02P 23/0022

(57) ABSTRACT

A method for operating a magnetic actuator comprises: ascertaining a mathematical model of the actuator which describes a change in a motor constant of the actuator as a function of the electrical drive power supplied; driving the actuator with a first electrical drive power as a function of a predetermined target force; ascertaining the change in the motor constant of the actuator on account of driving the actuator with the first electrical drive power via the mathematical model; ascertaining a correction value for the first electrical drive power as a function of the ascertained change in the motor constant; and driving the actuator with a second electrical drive power as a function of the first electrical drive power and the ascertained correction value.

### CROSS-REFERENCE TO RELATED APPLICATIONS

The present application is a continuation of, and claims benefit under 35 USC 120 to, international application PCT/EP2021/057258, filed Mar. 22, 2021, which claims benefit under 35 USC 119 of German Application No. 10 2020 204 415.5, filed Apr. 6, 2020. The entire disclosure of these applications are incorporated by reference herein.

### FIELD

The present disclosure relates to a method for operating a magnetic actuator, to a drive device for a magnetic actuator, to an optical system comprising a correspondingly controlled actuator, and to a lithography apparatus comprising such an optical system.

### BACKGROUND

Magnetic actuators having a permanent magnet and an electrical conductor arrangement are known. If a current flows through the electrical conductor arrangement, a magnetic field is induced and interacts with the magnetic field of the permanent magnet. This interaction is manifested for example in a mechanical force that acts between the electrical conductor arrangement and the permanent magnet. If the force rises linearly as current rises, the actuator can be characterized by a motor constant, for example. In this case, the motor constant corresponds to the proportionality factor between force and current.

In this case, the magnitude of the force depends primarily on geometric factors and the strength of the respective magnetic fields. The interaction results in heating of the permanent magnet. The greater the current, the more intense the heating. On account of the heating, the magnetization and thus the magnetic field strength of the permanent magnet decrease, which results in a reduction of the effective force. It can also be stated that the motor constant decreases. In order to attain a force that is constant over time, the current is increased.

Known controllers for magnetic actuators comprise for example temperature sensors on the permanent magnet in order to take account of the temperature dependence of the motor constant. This approach is technically complex since, for example, a structural space is restricted, since the actuators are operated in a vacuum, and since a complex calculation of the actual temperature of the permanent magnet on the basis of the detected temperature at the surface thereof has to be carried out. Moreover, such feedback control only intervenes if the temperature also increases at the surface of the permanent magnet. Furthermore, this approach can be unsatisfactory since the temperature dependence of the motor constant for a respective actuator has to be known accurately, which is often not the case, which is why it can be the case that only a minor advantage is attained despite the high complexity.

### SUMMARY

Optical systems having relatively high desired precision, such as in microlithography, for example, may profit from an improved control method for magnetic actuators.

The present disclosure seeks to provide an improved method for operating a magnetic actuator.

In accordance with a first aspect, the disclosure provides a method for operating a magnetic actuator, for example for actuating an optical element in an optical system, the actuator being configured for providing a mechanical force as a function of an electrical drive power. A first step involves ascertaining a mathematical model of the actuator which describes a change in a motor constant of the actuator as a function of an electrical drive power supplied. A second step involves driving the actuator with a first electrical drive power as a function of a predetermined target force. A third step involves ascertaining the change in the motor constant of the actuator on account of driving the actuator with the first electrical drive power via the mathematical model. A fourth step involves ascertaining a correction value for the first electrical drive power as a function of the ascertained change in the motor constant. A fifth step involves driving the actuator with a second electrical drive power as a function of the first electrical drive power and the ascertained correction value.

With this method, control of the actuator is effected taking account of the change in the motor constant owing to inherent heating during the operation of the actuator, as a result of which the control can be effected very precisely. Furthermore, an explicit temperature measurement of an actuator temperature is not required. The setup of the control can thus be simplified considerably, firstly because no temperature sensors are used, and secondly because a complex calculation of the temperature in the actuator on the basis of a temperature measurement at the surface thereof and the motor constant resulting therefrom are obviated. An additional factor is that the control does not rely on the measurement of a slowly changing variable, the temperature of the actuator, which is why the correction basically takes place without temporal delay. The change in the motor constant can also be taken into account a priori, for example, since the electrical drive power for the next control period in each case is already known or predetermined.

By way of example, during the exposure of a wafer in a lithography apparatus, a lens element is intended to be moved in accordance with a predetermined trajectory in order to achieve a high resolution. For this purpose, the actuator is driven with a corresponding drive power on the basis of the mathematical model. The actual drive power is detected metrologically and provided to the mathematical model as an input variable, for example, whereupon there is a change in the motor constant in the mathematical model, for example. Accordingly, in order to attain the correct position or deflection of the actuator, the drive power is corrected. It can therefore be stated that the mathematical model simulates the real behavior of the actuator on the basis of the actual drive power.

The magnetic actuator can comprise at least one permanent magnet and a conductor arrangement arranged relative to the permanent magnet in such a way that a mechanical force action arises if an electric current flows through the conductor arrangement. Examples of such actuators are Lorentz motors or Halbach motors. The current flowing through the conductor induces a magnetic field around the conductor, which magnetic field interacts with the magnetic field of the permanent magnet, in which case an attractive or repulsive force can arise, depending on the relative orientation of the magnetic field lines with respect to one another. In this case, the magnitude of the force depends on the magnitude of the current with which the conductor arrangement is energized. In this case, the force is for example proportional to a current intensity. The proportionality factor between force and current is referred to as motor constant, for example. The motor constant can be calculated for example as the derivative of the force with respect to the input current. In this case, the motor constant is individually different for example for a respective actuator. Owing to the temperature dependence of the magnetization of the permanent magnet, the motor constant likewise has a temperature dependence.

The actuator can be operated with an electrical drive power. The latter is given for example as the product of voltage and current. In the case of a constant voltage provided by a voltage source, for example, the drive power can therefore be changed by the current. The higher the drive power, the higher, too, the force provided by the actuator. However, the power dissipated in the actuator thus increases as well, as a result of which the permanent magnet of the actuator heats up. In the case of a permanent magnet, the magnitude of the magnetic flux density is dependent on the temperature, for which reason the force provided is also dependent on the temperature by way of the magnetic field. It can also be stated that the motor constant is dependent on the temperature.

In order to compensate for this dependence, it is proposed to ascertain a mathematical model of the actuator which describes the relationship between the motor constant and the temperature. It can be stated that the mathematical model describes the heating-up behavior of the permanent magnet as a function of the electrical drive power. Ascertaining the mathematical model can comprise selecting a basic model, for example on the basis of physical considerations, and defining parameter values of the basic model, for example on the basis of geometric properties of the actuator. A basic model can be understood to mean for example a theoretical model or else an empirical model of the heating-up behavior of the permanent magnet as a function of the electrical drive power.

For example, in a first step, the mathematical model is ascertained via a measurement of the relationship between the electrical drive power and the force action attained. By way of example, the actuator is operated with a constant high drive power for a relatively long time. The actuator begins to heat up until an equilibrium between the energy supplied and the thermal energy released by the actuator is established (thermal equilibrium).

Therefore, the change in the motor constant does not take place abruptly, but rather continuously with a time constant that is dependent for example on the power supplied and the heat capacity of the permanent magnet. At thermal equilibrium, the motor constant is constant. This measurement can also be referred to as a calibration measurement and it can be carried out using a closed control loop for the actuator while monitoring all relevant measurement variables. The calibration measurement can be carried out for example using a specific test stand. Alternatively or additionally, the calibration measurement for the actuator can be carried out in the installed state of the actuator, where “installed state” is understood to mean, in particular, that the actuator is installed in the system, for example the optical system, and in the function in which it is intended to be used later on.

The ambient conditions already correspond to those of later operation of the actuator, for which reason all possible effects which influence the heating-up behavior of the actuator are implicitly contained in the mathematical model, without these having to be explicitly known. Once the mathematical model of the actuator has been ascertained in this way, the actuator can be driven in a standard operating mode of the actuator taking account of a correspondingly corrected motor constant, as described below.

The second step can involve driving the actuator with a first electrical drive power as a function of a predetermined target force. The predetermined target force is predefined externally by an open-loop or closed-loop control device, for example. In this case, for example, a linear deflection of the actuator is attained via the predetermined target force, as a result of which a coupled optical element is deformed or displaced, for example. With known mechanical coupling, the predetermined target force can also be given by a predetermined target position of the actuator.

The third step can involve ascertaining the change in the motor constant of the actuator on account of driving the actuator with the first electrical drive power via the mathematical model. It can be stated that the mathematical model is evaluated or simulated for this purpose. By virtue of the mathematical model being simulated simultaneously with the drive power supplied to the actuator during the operation of the actuator, it can take account of all past values for the drive power. It can also be stated that the past temporal profile of the first electrical drive power influences the calculation. The heating of the actuator takes place with a time delay. Formally, the mathematical model can comprise for example a representation in the form of a differential equation.

The fourth step can involve ascertaining a correction value for the first electrical drive power as a function of the ascertained change in the motor constant. The correction value is for example the value which has to be added to the first electrical drive power in order to provide the predetermined target force.

The fifth step can involve driving the actuator with a second electrical drive power as a function of the first electrical drive power and the ascertained correction value. The second electrical drive power corresponds for example to the sum of the correction value and the first electrical drive power.

The method makes it possible, already before the occurrence of actuation errors that would subsequently have to be corrected by feedback control, as early as in the feedforward control, to take account of the effect of the change in the motor constant on account of the heating, which results in an improved actuation accuracy by the magnetic actuator.

In embodiments, the respective electrical drive power can be proportional to an input current at the actuator.

The actuator can be operated by a voltage source that provides a constant electrical voltage at the terminals. The voltage is then for example the proportionality factor between the input current and the electrical drive power.

In embodiments, the step of ascertaining the mathematical model can comprise a plurality of sub-steps. For example, the mathematical model is ascertained by the actuator being operated in a closed control loop. A first sub-step involves driving the actuator with the first electrical drive power for providing the predetermined target force. A second sub-step involves detecting the force provided by the actuator. A third sub-step involves controlling the first electrical drive power as a function of the detected force. This is done in such a way that the provided force corresponds to the predetermined target force and is constant over time, which can be monitored and thus controlled by way of the detected force. The change in force if the motor constant changes takes place instantaneously, such that a temporal error does not occur. A fourth sub-step involves detecting a change in the first electrical drive power over time. The first electrical drive power is not absolutely constant over time for example owing to the feedback control. A fifth sub-step involves ascertaining a model describing the temporal profile of the electrical drive power and/or ascertaining at least one parameter value of the mathematical model as a function of the detected change in the first electrical drive power over time.

In embodiments, position feedback control can be used instead of force feedback control. That is to say that the position of the actuator or of an element actuated by the latter is detected and kept constant, rather than the force of the actuator. In further embodiments, current feedback control can be effected, wherein the current is kept constant and the force provided by the actuator is detected.

Ascertaining the model comprises for example comparing the detected change in the electrical drive power over time with theoretically predicted profile curves. The model that has generated the profile curve with the least deviation with respect to the measurement data can be regarded as the best model. Optionally, parameter values of such a model are fitted to the measurement data. By way of example, a functional profile of the relationship between electrical drive power and force provided is already known for a specific actuator class, but exact values for parameters of the model may still be unknown for a specific actuator type. Such parameter values can be ascertained by fitting the model to the measurement data, an error function being minimized, for example, in order to ascertain the best parameter value or, in the case of a plurality of parameters to be fitted, the best set of parameter values.

The mathematical model ascertained in this way can comprise all possible effects which influence the heating-up behavior of the actuator and the change in the motor constant, without these having to be explicitly known or described by an equation.

In embodiments, detecting the electrical drive power supplied to the actuator is provided, the power being used in the third step for ascertaining the change in the motor constant.

For example, small fluctuations of the electrical drive power actually supplied can be taken into account in the control. For example, if the electrical drive power demanded changes greatly, for example for moving to a different position, the voltage source involves a specific finite time in order to provide the desired current, which can thus be taken into account. An accuracy of the compensation of the change in the motor constant is thus increased further. Moreover, reactive components in the electrical drive power that do not contribute to heating can be detected and correspondingly taken into account.

In embodiments, detecting a present actuator temperature is provided, the detected actuator temperature being used as feedback from the magnetic actuator in the third step for ascertaining the change in the motor constant.

This can implement a feedback of the actual actuator to the mathematical model. This can prevent the dynamic development of the mathematical model from drifting away from the actual conditions, which could occur owing to small discrepancies between the electrical drive power provided to the mathematical model as an input variable and the actual drive power. Unwanted drifting away of the mathematical model relative to the actual actuator state owing to inaccuracies of the mathematical model can likewise be avoided via the feedback. The detected actuator temperature corresponds to a coil temperature, for example, which can be derived from the coil current and the coil voltage. A temperature sensor is not mandatory in this case. The actuator temperature is periodically detected and supplied to the mathematical model, for example. As a result, the dynamic development of the mathematical model is repeatedly corrected, if the development of the model is diverging from reality. By way of example, in this case, the mathematical model comprises a Kalman filter that estimates the actuator temperature as a function of the electrical drive power (supplied to the mathematical model). Via comparison with the detected actuator temperature, errors in the electrical drive power supplied to the mathematical model or inaccuracies of the mathematical model can be corrected and drifting away of the modeling can thus be avoided.

In embodiments, the first step, which involves ascertaining the mathematical model, is carried out under ambient conditions which correspond to the envisaged operating conditions of the actuator.

Such embodiments can ensure that the conditions when ascertaining the mathematical model correspond to those which likewise prevail during operation of the actuator, for example in a lithography apparatus. For example, an ambient temperature and conditions which influence a dissipation of heat from the actuator (air pressure, molecular composition of the surrounding gas, air flows, cooling, etc.) are taken into account in this case.

In embodiments, the mathematical model is represented by at least one PT1 element and a PT0 element.

Such embodiments can allow the temporal behavior of the motor constant of the actuator to be represented via a suitable feedback control system, for example in the form of a block diagram. A PT0 element may also be referred to as a proportional element and a PT1 element may also be referred to as a 1st order delay element.

In this case, the PT0 element outputs a signal present at an input proportionally at an output without temporal delay. In the present case, the input corresponds for example to the current supplied to the actuator, the output corresponds to the force provided and the proportionality constant (gain factor) is the (temperature-dependent) motor constant of the actuator.

The PT1 element has a temporal delay, for which reason an output signal of the PT1 element is indeed proportional to the input signal, but follows the latter with a delay, wherein a functional relationship between input signal and output signal can be described by equation (1) below, for example. In equation (1), Y(t) describes the output signal at the point in time t, X denotes the input signal, t denotes time and T is the time constant, the value of which for example is dependent on physical parameters and can be measured experimentally for a given system.

Y(t)=X·(1−e^{-t/T}) equation (1).

Alternatively, equation (1) can also be written as a differential equation, as represented below in equation (2). In this case, the variables are as defined in equation (1) and d/dt is the differential operator with respect to time t.

d(T·Y(t))/dt+Y(t)=X(t) equation (2).

The PT1 element is suitable for example for describing heat conduction processes in solids. As already described above, under constant ambient conditions and with constant electrical power supplied, the actuator approaches a thermal equilibrium, which can be described by the PT1 element. Optionally, the PT1 element represents the heating of the actuator as a function of the electrical drive power, a proportionality factor (gain factor) between input and output being dependent on a temperature dependence of the motor constant. The output of the PT1 element is thus representative of the additional current used to maintain the predetermined target force in the case of a slowly changing motor constant. The PT1 element is characterized for example by the proportionality factor and the time constant.

In embodiments, the mathematical model can comprise further P elements, for example a plurality of series-connected PT1 elements, a PT2 element and/or even higher order elements. By way of example, the PT1 element can be replaced by a PTn element, where n indicates the order of the P element.

In embodiments, the mathematical model is selected on the basis of a theoretical description of the actuator, at least one parameter value of the model being determined in the first step.

In the present case, the theoretical description of the actuator is understood to mean for example a description of the relationship between the electrical drive power supplied and the force attained, and also a description of the heating-up behavior as a function of the electrical drive power. By way of example, a PT1 element is selected in order to describe the dynamic behavior of the actuator, with the proportionality factor and the time constant being determined in the first step.

Determining the at least one parameter value can also be referred to as calibrating the model or parameterizing the model.

In accordance with a second aspect, a method for operating an optical system is proposed.

The optical system has a number of optical elements, wherein at least one of the optical elements of the number is actuable via a coupled magnetic actuator. The actuator is operated for actuating the optical element via the method in accordance with the first aspect.

The actuation of the optical element, which can be for example a displacement, a rotation and/or a mechanical strain or deformation of the optical element, can be effected particularly precisely. The actuation of the optical element can make it possible for example to compensate for optical aberrations of the optical system and/or to realize variable beam guidance.

The optical system is for example a beam guiding system of an optical instrument, such as a microscope, a telescope, an optical measuring system or a lithography apparatus. It should be pointed out that the optical system is not limited to the visible wavelength range of the electromagnetic spectrum, but rather can go beyond that. This should also be understood to include optical systems for gamma radiation, x-ray radiation or UV radiation, for example EUV radiation, but also for IR radiation, microwave radiation or terahertz radiation.

The optical system can comprise different optical elements depending on the wavelength range. In this case, an optical element is any element which is arranged in a targeted manner for influencing a beam path of radiation in the optical system. Examples of the optical element are for example lens elements, mirrors, gratings and stops.

The beam path of the optical system can be influenced in a targeted manner by the actuation of the at least one optical element. In this regard, for example, a focal plane of a lens element or of a mirror can be displaced or a stop can be adjusted. Consequently, different optical configurations of the optical system can be attained via the actuation. Furthermore, aberrations, such as a distortion or a wavefront aberration, for example, can also be compensated for via the actuation. An accuracy or imaging quality of the optical system can thus be increased.

In the present case, the actuation of the optical element by the actuator in accordance with the method of the first aspect can be desirable since, via the mathematical model, the change in the motor constant of the actuator can be ascertained continuously during on-going operation and the electrical drive power can be correspondingly corrected. In this case, the correction is effected for example in the context of the feedforward control, that is to say without the actual deflection attained having to be detected. This results in an improved accuracy in conjunction with reduced complexity.

The embodiments and features described for the method in accordance with the first aspect are also applicable to the proposed method in accordance with the second aspect.

In accordance with a third aspect, a computer program product is proposed which comprises instructions which, when the program is executed by a computer, cause the latter to carry out the method in accordance with the first or second aspect.

A computer program product, such as e.g. a computer program, can be provided or supplied, for example, as a storage medium, such as e.g. a memory card, a USB stick, a CD-ROM, a DVD, or else in the form of a downloadable file from a server in a network. By way of example, in a wireless communications network, this can be effected by transferring an appropriate file with the computer program product or the computer program.

In accordance with a fourth aspect, a drive device for driving a magnetic actuator for providing a mechanical force as a function of an electrical drive power is proposed. The drive device comprises a modeling unit for providing a mathematical model of the actuator which describes a change in a motor constant of the actuator as a function of the electrical drive power, a driving unit for driving the actuator with a first electrical drive power as a function of a predetermined target force, an evaluation unit for ascertaining a change in the motor constant of the actuator on account of driving the actuator with the first electrical drive power and as a function of the mathematical model provided by the modeling unit, and a correction unit for ascertaining a correction value for the first electrical drive power as a function of the ascertained change in the motor constant of the actuator. The driving unit is configured to drive the actuator with a second electrical drive power as a function of the first electrical drive power and the ascertained correction value.

The drive device can be operated in accordance with the method in accordance with the first aspect. The embodiments and features of the method of the first aspect are applicable, mutatis mutandis, to the drive device.

The drive device is for example part of a feedforward control facility for controlling the magnetic actuator. The drive device and/or the respective unit, such as the modeling unit, driving unit, evaluation unit and correction unit, can be implemented in terms of hardware and/or in terms of software. In the case of an implementation in terms of hardware, the drive device and/or the respective unit can be embodied as a computer or as a micro-processor, for example. In the case of an implementation in terms of software, the drive device and/or the respective unit can be embodied as a computer program product, as a function, as a routine, as part of a program code or as an executable object.

The drive device can comprise a voltage or current source in order to drive the actuator.

In embodiments, a detection unit for detecting an electrical drive power supplied to the actuator is provided, the evaluation unit being configured for ascertaining the change in the motor constant as a function of the detected electrical drive power.

The detection unit can comprise for example a voltage measuring unit, which detects the voltage present at the actuator, and a current measuring unit, which detects the current supplied to the actuator. As a result, the actual electrical drive power is accurately known at every point in time, which can accordingly be taken into account when ascertaining the correction value. As a result, the actuator can be operated even more accurately, for example with an even higher positioning accuracy.

In order to achieve a higher accuracy, in embodiments, the detection unit can furthermore detect a phase angle of current and voltage in order that the electrical drive power actually supplied is determined even more precisely. This can be desirable particularly at high switching frequencies, that is to say if the position of the actuator is changed or adapted frequently per unit time, since phase differences between these two variables can occur precisely during switchover.

In embodiments, a further detection unit for detecting a present actuator temperature is provided. In this case, the detected actuator temperature can be supplied to the mathematical model as physical feedback in order to correct measurement errors. The present actuator temperature corresponds to a coil temperature of a coil of the actuator, for example.

In accordance with a fifth aspect, a mechanical system comprising at least one magnetic actuator for actuating an actuating element is proposed. The actuator is configured for providing a mechanical force as a function of an electrical drive power. The mechanical system comprises at least one drive device for driving the magnetic actuator in accordance with the fourth aspect.

The mechanical system is embodied for example as a manipulator in a robot system. The mechanical system can be arranged in an automation system for producing or processing objects. Particularly during the production or processing of high precision parts, such as in microsystems technology or medical technology, for example, the mechanical system has an actuation accuracy by way of the actuator is effected very precisely.

In accordance with a sixth aspect, an optical system having a number of optical elements proposed, wherein at least one of the optical elements of the number is actuable via a coupled magnetic actuator. The actuator is configured for providing a mechanical force as a function of an electrical drive power. The optical system comprises at least one drive device for driving the magnetic actuator for actuating the optical element in accordance with the fourth aspect.

The actuation of the optical element, which can bring about for example a displacement, a rotation and/or a mechanical deformation of the optical element, is effected particularly precisely. Therefore, a correction of an optical aberration that is provided via the actuation of the optical element can be improved. The optical system can be operated in accordance with the method in accordance with the second aspect.

The optical system forms for example a beam path of an optical instrument, such as a microscope, a telescope or a lithography apparatus. It should be pointed out that the optical system is not limited to the visible wavelength range of the electromagnetic spectrum, but rather can go beyond that. This should also be understood to include optical systems for gamma radiation, x-ray radiation or UV radiation, but also for IR radiation, microwave radiation or terahertz radiation.

The optical system can comprise different optical elements depending on the wavelength range. In this case, an optical element is any element which is arranged in a targeted manner for influencing a beam path of radiation in the optical system. Examples of the optical element are for example lens elements, mirrors, gratings and stops.

The beam path of the optical system can be influenced in a targeted manner by the actuation of the at least one optical element. In this regard, for example, a focal plane of a lens element or of a mirror can be displaced or a stop can be adjusted. Consequently, different optical configurations of the optical system can be attained via the actuation. Furthermore, aberrations, such as a distortion or a wavefront aberration, for example, can also be compensated for via the actuation. An imaging quality of the optical system can thus be increased.

In the present case, the actuation of the optical element by the actuator in accordance with the method of the first aspect can be desirable, for example, if the optical element is intended to be actuated along a predetermined trajectory, that is to say is intended to be deflected completely in a direction within 10 seconds, for example. The electrical drive power with which the actuator will be driven is then also already known beforehand owing to the known relationship between electrical drive power and force or deflection provided. Accordingly, via the mathematical model, the change in the motor constant of the actuator can be ascertained and the electrical drive power can be correspondingly corrected. In this case, the correction is effected for example in the context of the feedforward control, that is to say without the deflection actually attained having to be detected.

In accordance with a seventh aspect, a lithography apparatus comprising an optical system in accordance with the sixth aspect is proposed.

The lithography apparatus is a DUV or EUV lithography apparatus, for example. The features of the optical system are applicable, mutatis mutandis, to the lithography apparatus.

“A(n); one” in the present case should not necessarily be understood as restrictive to exactly one element. Rather, a plurality of elements, such as, for example, two, three or more, can also be provided. Any other numeral used here, too, should not be understood to the effect that there is a restriction to exactly the stated number of elements. Rather, numerical deviations upwards and downwards are possible, unless indicated to the contrary.

Further possible implementations of the disclosure also comprise not explicitly mentioned combinations of any features or embodiments that are described above or below with respect to the exemplary embodiments. In this case, a person skilled in the art will also add individual aspects as improvements or supplementations to the respective basic form of the disclosure.

Further configurations and aspects of the disclosure are the subject matter of the dependent claims and also of the exemplary embodiments of the disclosure described below. The disclosure is explained in greater detail below on the basis of embodiments with reference to the appended figures.

### BRIEF DESCRIPTION OF THE DRAWINGS

FIG. 1 shows a schematic block diagram of an exemplary embodiment of a method for operating a magnetic actuator;

FIG. 2 schematically shows an exemplary embodiment of a magnetic actuator;

FIG. 3 shows an exemplary diagram of a motor constant at various temperatures;

FIG. 4 shows an exemplary diagram of a change in a drive power for providing a constant force;

FIG. 5 shows a schematic block diagram of a mathematical model of a magnetic actuator;

FIG. 6 shows a schematic block diagram of a mathematical model of a magnetic actuator;

FIG. 7 shows a schematic block diagram of an arrangement for ascertaining a mathematical model;

FIG. 8 shows a schematic block diagram of a drive device for driving a magnetic actuator;

FIG. 9 schematically shows an exemplary embodiment of an optical system;

FIG. 10A shows a schematic view of an embodiment of an EUV lithography apparatus; and

FIG. 10B shows a schematic view of an embodiment of a DUV lithography apparatus.

### EXEMPLARY EMBODIMENTS

Identical elements or elements having an identical function have been provided with the same reference signs in the figures, unless indicated to the contrary. It should also be noted that the illustrations in the figures are not necessarily true to scale.

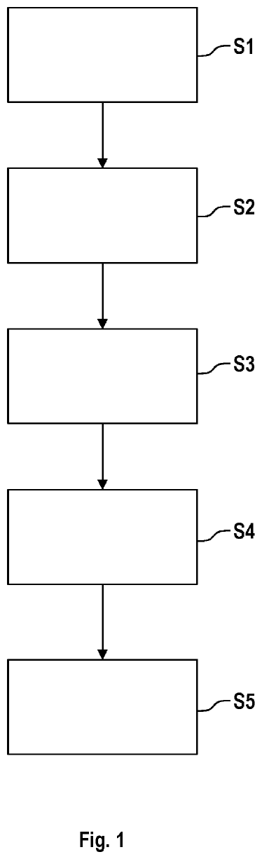

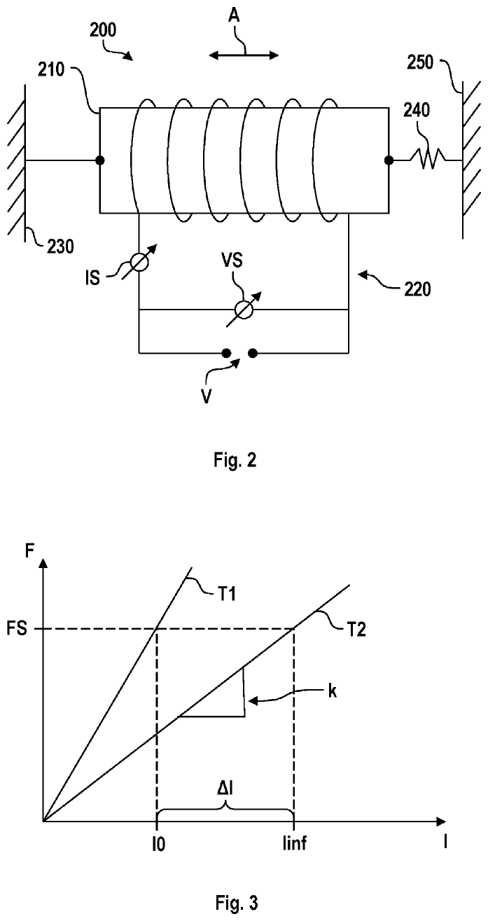

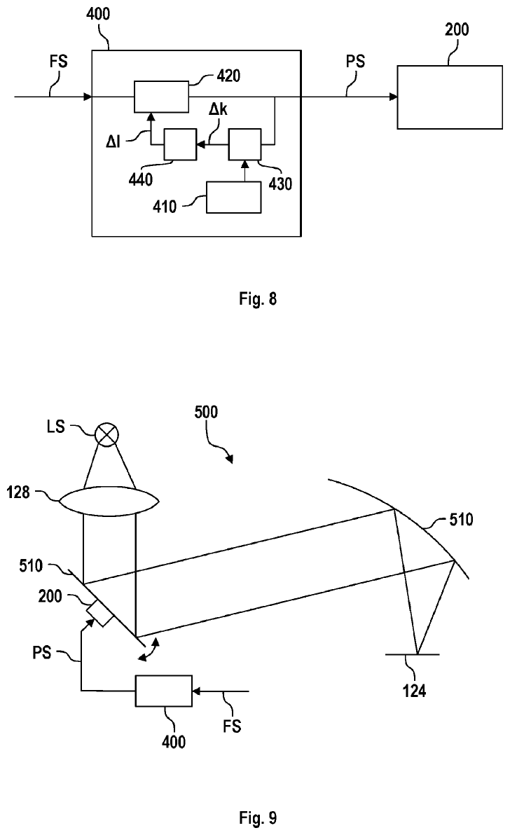

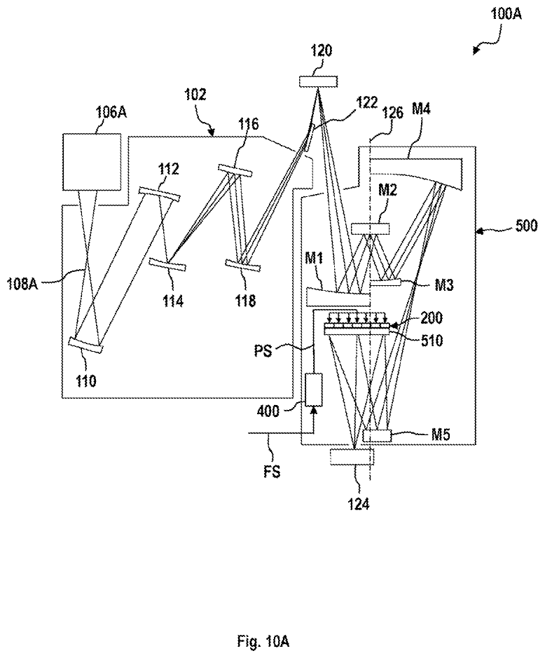

FIG. 1 shows a schematic block diagram of an exemplary embodiment of a method for operating a magnetic actuator 200 (see FIGS. 2, 7-9, 10A and 10B). The actuator 200 is configured for providing a mechanical force A (see FIG. 2) as a function of an electrical drive power PS (see FIG. 8 or 9).

A first step S1 involves ascertaining a mathematical model of the actuator 200 which describes a change in a motor constant k (see FIG. 3) of the actuator 200 as a function of the electrical drive power PS supplied. The relationship between the electrical drive power PS and the motor constant k is explained in greater detail below with reference to FIGS. 3-6.

A second step S2 involves driving the actuator 200 with a first electrical drive power PS as a function of a predetermined target force FS (see FIGS. 3, 8, 9, 10A and 10B). The first electrical drive power PS is determined on the basis of the (known) motor constant k under specific conditions, for example normal conditions.

A third step S3 involves ascertaining the change in the motor constant k of the actuator 200 on account of driving the actuator 200 with the first electrical drive power PS via the mathematical model. By way of example, the mathematical model is evaluated, for example the electrical drive power PS serving as an input variable.

A fourth step S4 involves ascertaining a correction value for the first electrical drive power PS as a function of the ascertained change in the motor constant k. The correction value is for example a correction value ΔI (see FIG. 3, 4 or 8) for the drive current I (see FIG. 2 or 7) applied to the actuator 200.

A fifth step S5 involves driving the actuator 200 with a second electrical drive power PS as a function of the first electrical drive power PS and the ascertained correction value. The second electrical drive power PS is for example a sum of the first electrical drive power PS and the correction value.

The change in the motor constant k owing to heating of the actuator 200 is compensated for in this way, such that the force A provided by the actuator 200 corresponds to the demanded target force FS. By way of example, the provided force A given a constant target force FS is likewise constant, even though the motor constant k changes slowly, without the need for explicit force feedback control for the actuator 200. In this case, the ascertainment of the mathematical model can be accorded particular importance since this substantially defines the accuracy of the compensation.

FIG. 2 schematically shows an exemplary embodiment of a magnetic actuator 200 that can be operated for example in accordance with the method from FIG. 1. The magnetic actuator 200 comprises a permanent magnet 210 surrounded by a conductor arrangement 220, which here forms a coil. On one side, the permanent magnet 210 of the actuator 200 is mechanically connected to the element 230 to be actuated. This ensures that the force

A provided by the actuator 200 is transmitted to the element 230. On the other side, the permanent magnet 210 is secured to a rigid force frame 250 via a coupling element 240. The coupling element 240 transmits the force opposing the force A to the force frame 250, which forms a mechanical fixed point for the actuator 200. The coupling element 240 is embodied as a spring, for example, which defines a rest position of the permanent magnet 210 in relation to the force frame 250 and permits a relative movement between the permanent magnet 210 and the force frame 250. The deflection is proportional to the force A, for example, for which reason the two terms can be used interchangeably with one another.

The conductor arrangement 220 is connected to a voltage or current source V, which provides an electrical drive power PS (see FIG. 8, 9, 10A or 10B). The electrical drive power PS can be calculated in accordance with Ohm's law, for example, as the product of the drive voltage VS and the drive current IS. In order to achieve a higher accuracy, a phase angle of current and voltage can be taken into account. The conductor arrangement 220 can be fixed relative to the force frame 250.

If the voltage source V energizes the conductor arrangement 220 with a drive current IS, an induced magnetic field builds up for example within the coil, i.e. in the region of the permanent magnet 210. The magnetic field interacts with the magnetic field of the permanent magnet 210, thus resulting in a mechanical force action. Furthermore, the interaction leads to heating of the permanent magnet 210. The heating has the effect that the magnetization of the permanent magnet 210 becomes weaker, which affects the magnitude of the force action. This is described in more specific detail below with reference to FIG. 3.

FIG. 3 shows an exemplary diagram of a motor constant k for an electrical actuator 200, for example one of those shown in FIG. 2, FIGS. 7-8, FIG. 10A or FIG. 10B, at two different temperatures T1 and T2.

The diagram shows a current axis I and a force axis F. The lines T1 and T2 correspond to the functional relationship of the provided force of the magnetic actuator 200 as a function of the current I with which the actuator 200 is driven. The current I could also be replaced by the voltage or generally the electrical power. The motor constant k of the actuator 200 is given by the gradient of the respective line T1, T2. In this case, the line T1 corresponds to a temperature of 25° C., for example, and the line T2 corresponds to a temperature of 45° C., for example. It is immediately clear from this illustration that, at different temperatures, different currents are also used in order to attain the same force, for example the target force FS. In this regard, for example, from a first current value I0 that is sufficient to attain the target force FS at 25° C. (line T1), a current value Iinf increased by a difference magnitude ΔI is present in order to attain the same target force FS at the temperature of 45° C. (line T2). Since the temperature of the actuator 200 increases principally owing to the driving with the electrical drive power PS (and accordingly decreases when the electrical drive power PS decreases), the dynamic behavior of the actuator 200 can be simulated with the aid of a mathematical model on the basis of the known electrical drive power PS.

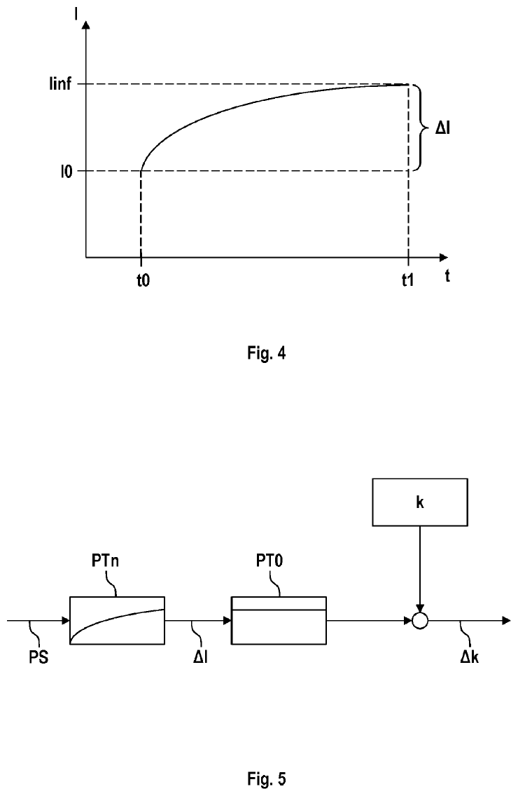

FIG. 4 shows an exemplary diagram of a change in a drive power for providing a constant force, for example for one of the magnetic actuators 200 shown in FIG. 2, FIGS. 7-9, FIG. 10A or FIG. 10B. The diagram has a horizontal time axis t and a vertical current axis I, the current I being regarded here as representative of the electrical power. At a first point in time t0, the actuator 200 is energized with a first current I0. As already explained above, this leads to heating of the permanent magnet 210 (see FIG. 2) and consequently to a reduced motor constant k (see FIG. 3). In order nevertheless to provide the same force, the actuator 200 is operated with a drive current IS that rises continuously in accordance with the temperature of the permanent magnet 210. At a point in time t1, for example, a thermal equilibrium is reached in the permanent magnet 210, for which reason the motor constant k does not change further and the drive current IS remains stable at a value of Iinf=I0+ΔI. The period of time that elapses until the thermal equilibrium is reached depends on various factors, for example a heat capacity and a thermal conductivity of the actuator 200. The behavior of the actuator 200 in terms of time dynamics can be represented via a P feedback control system, for example, as is explained below with reference to FIG. 5.

FIG. 5 shows a schematic block diagram of a mathematical model of a magnetic actuator 200, for example of the actuator 200 illustrated in FIG. 2, FIGS. 7-9, FIG. 10A or FIG. 10B. The mathematical model is represented here in the form of a P feedback control system having an nth order P element PTn and a proportional element PT0 in a series circuit. Taking account of a nominal motor constant k, for example the motor constant k of the modeled actuator 200 under normal conditions, the resulting output value of the P feedback control system is the change Δk in the motor constant k. The change Δk in the motor constant k can be written as a function of the drive current IS and time t for example in accordance with equation (3).

Δk(t)=k·ΔI(t)/(IS+ΔI(t)) equation (3).

In this case, ΔI(t) is the temporally variable component of the drive current IS, as illustrated for example in the diagrams in FIG. 3 or 4.

The input variable for the P feedback control system is the electrical drive power PS. The PTn element, which is a PT1 element, for example, outputs the correction value ΔI for the current as output value. The PTn element is characterized by at least one time constant and a gain factor, for example. The PT0 element describes the change Δk in the motor constant k for example on the basis of the correction value ΔI and the nominal motor constant k.

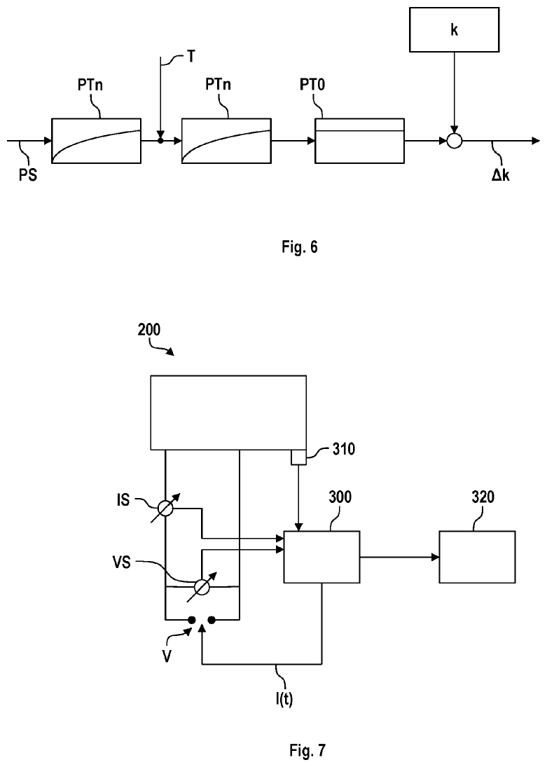

FIG. 6 shows a further schematic block diagram of a mathematical model of a magnetic actuator 200, for example of the actuator 200 illustrated in FIG. 2, FIGS. 7-9, FIG. 10A or FIG. 10B. Here, in a similar manner to FIG. 5, the mathematical model is represented in the form of a P feedback control system. In contrast to FIG. 5, here two nth order P elements PTn are arranged in a series circuit with a proportional element PT0. The overall transfer function of the P feedback control system illustrated corresponds to that of the system illustrated in FIG. 5. In order to ensure that the mathematical model does not drift away from reality, which could occur for example as a result of model inaccuracies or small discrepancies between the electrical drive power PS provided to the mathematical model as input variable and the actual drive power, here an actuator temperature T, optionally the coil temperature, is supplied to the mathematical model as a physical measurement variable of the magnetic actuator 200. This ensures that the dynamic development of the mathematical model remains coupled to the actual behavior of the actuator 200.

The first PTn element describes for example the transfer function between the electrical drive power PS and a coil temperature T of the magnetic actuator 200. If the electrical drive power PS supplied to the mathematical model is erroneous, an erroneous coil temperature T arises as a consequence. By virtue of the coil temperature T being supplied to the model as a measurement value in the present case, measurement errors, for example of the electrical drive power PS, can be corrected. The coil temperature T can be detected on the basis of a coil voltage and a coil current.

FIG. 7 shows a schematic block diagram of an arrangement for ascertaining a mathematical model of a magnetic actuator 200. In this case, the magnetic actuator 200 is operated via an electrical drive circuit controlled by a control unit 300. A sensor unit 310 is assigned to the actuator 200, which sensor unit detects a provided force or an effected deflection of the actuator 200 and outputs it to the control unit 300. Furthermore, a current measuring unit for measuring the drive current IS and a voltage measuring unit for measuring a drive voltage VS are arranged in the electrical circuit. The control unit 300 effects control with respect to the force or deflection of the actuator 200, for example. For example, the drive voltage VS is constant, and so the change in the motor constant k (see FIG. 3) is compensated for by changing the drive current IS. The control unit 300 therefore controls the voltage source V via a temporally variable current I(t).

An ascertaining unit 320 receives all measurement, sensor and control signals, for example, from the control unit 300. In this regard, by recording the temporally variable control signal I(t), it is possible to identify the PT0 element and the PTn element from FIG. 5, that is to say that it is possible to ascertain the parameter values of the PT0 element and of the PTn element. The ascertaining unit 320 can apply various automatic algorithms in order to identify the mathematical model. In this case, a plurality of different models can be predefined, for example, from which the ascertaining unit 320 selects the best model. In this case, the “best model” can be that model which has the smallest deviation in accordance with a specific quality factor. The ascertaining unit 320 can for example also comprise a neural network, which at least partly carries out or assists the ascertaining of the mathematical model. By way of example, such a neural network can be used in order to make a preselection from the plurality of possible mathematical models.

FIG. 8 shows a schematic block diagram of a drive device 400 for driving a magnetic actuator 200, for example the magnetic actuator 200 shown in FIG. 2, 7, 9, 10A or 10B. The drive device 400 is configured for example for carrying out the method described with reference to FIG. 1. A predetermined target force FS is supplied to the drive device 400 externally, for example from a control computer (not shown). A predetermined target position of the actuator 200 can also be considered instead of the predetermined target force FS. The drive device 400 is configured to drive the actuator 200 with an electrical drive power PS, such that the actuator 200 provides the predetermined target force FS and thus brings about movement to the predetermined target position.

For this purpose, the drive device 400 comprises a driving unit 420 comprising for example a controlled voltage or current source V (see FIG. 2 or 7), which can provide the electrical drive power PS. Furthermore, the drive device 400 comprises an evaluation unit 430 configured to evaluate a mathematical model of the actuator 200, provided by a modeling unit 410, as a function of the present drive power PS. By way of example, the mathematical model is given in the form of a P feedback control system (see FIG. 5 or 6). The evaluation unit 430 supplies the drive power PS as input signal and obtains as output signal a value for the change Δk in the motor constant k of the actuator 200. The value Δk is supplied to a correction unit 440, which ascertains a correction value ΔI for the drive power PS on the basis of the value Δk, which correction value in this example is represented as a correction value ΔI for the drive current IS (see FIG. 2 or 7).

The driving unit 420 changes the drive power PS by the correction value ΔI; by way of example, the drive current IS is increased or decreased by the correction value ΔI. The mathematical model is constantly evaluated on the basis of the drive power PS. Since all earlier drive powers PS were likewise supplied to the mathematical model, these are taken into account in the present state of the mathematical model. Therefore, the mathematical model can correctly represent even processes exhibiting a great time delay, as a function of the drive power PS. In many applications, the target force FS or the corresponding target position changes with a high frequency of 1-100 kHz, the motor constant k changing more slowly by orders of magnitude, which is owing to the comparatively slow change in the actuator temperature in reaction to a changed drive power PS. By virtue of the correction of the electrical drive power PS on the basis of the mathematical model, it is possible to compensate for the change Δk in the motor constant k of the actuator 200 as early as before intervention by a closed control loop, and therefore firstly more rapidly and secondly with a lower complexity, whereby a precision of the actuation by the actuator 200 is improved.

FIG. 9 schematically shows an exemplary embodiment of an optical system 500. The optical system 500 is for example an illumination beam path, for example in a microscope. The optical system 500 comprises a light source LS, the light from which is collimated by a first lens element 128. The collimated light is incident on a first optical element 510, which is embodied as a plane mirror and is mounted so as to be displaceable about an axis via a magnetic actuator 200 in order to control a direction of the collimated light. The light is reflected onto a second optical element 510, which is embodied here as a parabolically curved mirror that focuses the light onto a point on an object 124.

The magnetic actuator 200 is for example the magnetic actuator 200 illustrated in FIG. 2, FIG. 7 or FIG. 8. In this case, the magnetic actuator 200 is controlled for example by a drive device 400, as described with reference to FIG. 8, and in accordance with the method described with reference to FIG. 1. As described with reference to FIG. 8, a predetermined target force FS, which here corresponds to a predetermined angle of the plane mirror 510 in relation to the incident light and thus to a specific illumination position on the object 124, is supplied to the drive device 400 externally. The drive device 400 thereupon drives the actuator 200 with the electrical drive power PS, such that the plane mirror 510 is adjusted to the predetermined angle. In order to counteract a slow change in the angle and thus a displacement of the illumination position owing to the heating of the actuator 200, the electrical drive power PS is constantly compensated for by the drive device 400 on the basis of the mathematical model, as described with reference to FIG. 8. The illumination of the object 124 is thus possible very precisely. It goes without saying that the drive device 400 does not exclude more extensive feedback control, for example via a closed control loop, but rather can be used in addition thereto.

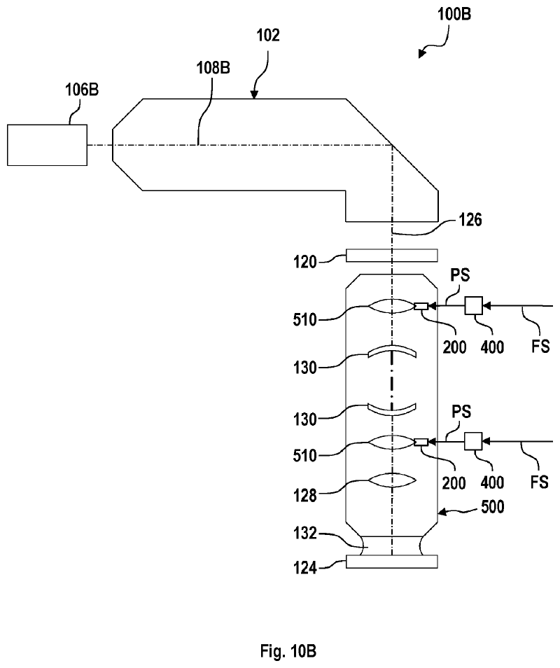

FIG. 10A shows a schematic view of an EUV lithography apparatus 100A, which comprises a beam shaping and illumination system 102 and an optical system 500 embodied as a projection system. In this case, EUV stands for “extreme ultraviolet” and denotes a wavelength of the working light of between 0.1 nm and 30 nm. The beam shaping and illumination system 102 and the projection system 500 are respectively provided in a vacuum housing (not shown), each vacuum housing being evacuated with the aid of an evacuation device (not shown). The vacuum housings are surrounded by a machine room (not shown), in which driving apparatuses for mechanically moving or setting optical elements are provided. Furthermore, electrical controllers and the like may also be provided in the machine room.

The EUV lithography apparatus 100A has an EUV light source 106A. A plasma source (or a synchrotron), which emits radiation 109A in the EUV range (extreme ultraviolet range), that is to say for example in the wavelength range of 5 nm to 20 nm, can for example be provided as the EUV light source 106A. In the beam shaping and illumination system 102, the EUV radiation 109A is focused and the desired operating wavelength is filtered out from the EUV radiation 109A. The EUV radiation 109A generated by the EUV light source 106A has a relatively low transmissivity through air, for which reason the beam guiding spaces in the beam shaping and illumination system 102 and in the projection system 500 are evacuated.

The beam shaping and illumination system 102 illustrated in FIG. 10A has five mirrors 110, 112, 114, 116, 118. After passing through the beam shaping and illumination system 102, the EUV radiation 109A is guided onto a photomask (reticle) 120. The photomask 120 is likewise embodied as a reflective optical element and can be arranged outside the systems 102, 500. Furthermore, the EUV radiation 109A can be directed onto the photomask 120 via a mirror 122. The photomask 120 has a structure which is imaged onto an object 124, for example a wafer or the like, in a reduced fashion via the projection system 500.

The projection system 500 (also referred to as a projection lens) has five mirrors M1 to M5 and an optical element 510 for imaging the photomask 120 onto the wafer 124, the optical element being actuable via a plurality of magnetic actuators 200. In this case, individual mirrors M1 to M5 and the optical element 510 of the projection system 500 can be arranged symmetrically in relation to an optical axis 126 of the projection system 500. It should be noted that the number of mirrors M1 to M5 of the EUV lithography apparatus 100A is not restricted to the number shown. A greater or lesser number of mirrors M1 to M5 can also be provided. Furthermore, the mirrors M1 to M5 are generally curved on their front sides for beam shaping. Furthermore, individual or all of the mirrors M1 to M5 can be configured as actuable via one or more actuators 200, in a corresponding manner to the optical element 510.

The actuators 200 correspond to those shown in FIG. 2 or FIGS. 7-9, for example. In the present case, the optical element 510 is configured as a mirror, the front side of which is deformable by the actuators 200. By way of example, optical aberrations can be compensated for by the optical element 510, with the result that a resolution of the EUV lithography apparatus 100A is increased. Each of the actuators 200 is driven via a drive device 400 assigned to it, as explained with reference to FIG. 8. In FIG. 10A, only one drive device 400 is illustrated, for reasons of clarity. As described above, the respective drive device 400 receives a predetermined target force FS that is intended to be applied or provided by the assigned actuator 200, and thereupon drives the assigned actuator 200 with the electrical drive power PS, which is continuously corrected or adapted as described above. In this case, the predetermined target force FS can comprise for example a predetermined temporal force profile.

FIG. 10B shows a schematic view of a DUV lithography apparatus 100B, which comprises a beam shaping and illumination system 102 and an optical system 500 embodied as a projection system. In this case, DUV stands for “deep ultraviolet” and denotes a wavelength of the working light of between 30 nm and 250 nm. As has already been described with reference to FIG. 10A, the beam shaping and illumination system 102 and the projection system 500 can be arranged in a vacuum housing and/or be surrounded by a machine room with corresponding driving apparatuses.

The DUV lithography apparatus 100B has a DUV light source 106B. By way of example, an ArF excimer laser that emits radiation 109B in the DUV range at 193 nm, for example, can be provided as the DUV light source 106B.

The beam shaping and illumination system 102 illustrated in FIG. 10B guides the DUV radiation 109B onto a photomask 120. The photomask 120 is embodied as a transmissive optical element and can be arranged outside the systems 102, 500. The photomask 120 has a structure which is imaged onto an object 124, for example a wafer or the like, in a reduced fashion via the projection system 500.

The projection system 500 has a plurality of lens elements 128, mirrors 130 and/or optical elements 510 for imaging the photomask 120 onto the wafer 124, the optical elements being actuable via magnetic actuators 200. In this case, individual lens elements 128, mirrors 130 and/or optical elements 510 of the projection system 500 can be arranged symmetrically relative to an optical axis 126 of the projection system 500. It should be noted that the number of lens elements 128 and mirrors 130 of the DUV lithography apparatus 100B is not restricted to the number shown. A greater or lesser number of lens elements 128 and/or mirrors 130 can also be provided. Furthermore, the mirrors 130 are generally curved on their front sides for beam shaping. Furthermore, individual or all of the lens elements 128 and/or mirrors 130 can be configured as actuable via one or more actuators 200, in a corresponding manner to the optical element 510.

The actuators 200 correspond to those shown in FIG. 2 or FIGS. 7-9, for example. The optical elements 510 are configured as displaceable lens elements in the present case. By way of example, optical aberrations can be compensated for by the optical element 510, with the result that a resolution of the DUV lithography apparatus 100B is increased. Each of the actuators 200 is driven via a drive device 400 assigned to it, as explained with reference to FIG. 8. As described above, the respective drive device 400 receives a predetermined target force FS that corresponds here to a predetermined position of the respective lens element 510 that is intended to be applied or provided by the assigned actuator 200, and thereupon drives the assigned actuator 200 with the electrical drive power PS, which is continuously corrected or adapted as described above.

An air gap between the last lens element 128 and the wafer 124 can be replaced by a liquid medium 132 having a refractive index>1. The liquid medium 132 can be high-purity water, for example. Such a construction is also referred to as immersion lithography and has an increased photolithographic resolution. The medium 132 can also be referred to as an immersion liquid.

Although the present disclosure has been described on the basis of exemplary embodiments, it is modifiable in diverse ways.

### LIST OF REFERENCE SIGNS

100A EUV lithography apparatus
100B DUV lithography apparatus
102 Beam shaping and illumination system
106A EUV light source
106B DUV light source
109A EUV radiation
109B DUV radiation
110 Mirror
112 Mirror
114 Mirror
116 Mirror
118 Mirror
120 Photomask
122 Mirror
124 Object
126 Optical axis
128 Lens element
130 Mirror
132 Medium
200 Actuator
210 Permanent magnet
220 Conductor arrangement
230 Actuated element
240 Coupling element
250 Force frame
300 Control unit
310 Detection unit
320 Ascertaining unit
400 Drive device
410 Modeling unit
420 Driving unit
430 Evaluation unit
440 Correction unit
500 Optical system
510 Optical element
A Force
FS Target force
I Current
I0 Current value
Iinf Current value
IS Drive current
K Motor constant
LS Light source
M1 Mirror
M2 Mirror
M3 Mirror
M4 Mirror
M5 Mirror
PS Electrical drive power
PT0 Proportional element
Ptn nth order P element
S1 Method step
S2 Method step
S3 Method step
S4 Method step
S5 Method step
t Time
t0 Point in time
t1 Point in time
T Temperature
T1 Line
T2 Line
V Voltage/current source
VS Drive voltage
ΔI Correction value
Δk Change

What is claimed is:

1. A method of operating a magnetic actuator configured to provide a mechanical force as a function of an electrical drive power, the method comprising:
determining a mathematical model of the magnetic actuator, the mathematical model describing a change in a motor constant of the magnetic actuator as a function of an electrical drive power supplied to the magnetic actuator;
driving the magnetic actuator with a first electrical drive power as a function of a target force;
using the mathematical model to determine the change in the motor constant of the magnetic actuator due to driving the magnetic actuator with the first electrical drive power;
determining a correction value for the first electrical drive power as a function of the change in the motor constant; and
driving the magnetic actuator with a second electrical drive power as a function of the first electrical drive power and the correction value.

2. The method of claim 1, further comprising using the magnetic actuator to actuate an optical element.

3. The method of claim 1, wherein the optical element is in an optical system.

4. The method of claim 1, wherein the first electrical drive power is proportional to an input current at the magnetic actuator.

5. The method of claim 1, wherein determining the mathematical model comprises:
driving the magnetic actuator with the first electrical drive power to provide the target force;
detecting the force provided by the magnetic actuator;
controlling the first electrical drive power as a function of the detected force;
detecting a change in the first electrical drive power over time; and
providing a model describing the temporal profile and/or determining a parameter value of the model as a function of the detected change in the first electrical drive power over time.

6. The method of claim 1, further comprising:
detecting the electrical drive power supplied to the magnetic actuator; and
using the electrical drive power when determining the change in the motor constant.

7. The method of claim 1, further comprising:
detecting a present actuator temperature; and
using the actuator temperature as feedback when determining the change in the motor constant.

8. The method of claim 1, wherein determining the mathematical model is performed under ambient conditions which correspond to envisaged operating conditions of the magnetic actuator.

9. The method of claim 1, the mathematical model is represented by at least one PT1 element and a PT0 element.

10. The method of claim 1, further comprising selecting the mathematical model based on a theoretical description of the magnetic actuator, wherein determining the mathematical model determining a parameter value of the mathematical model.

11. One or more machine-readable hardware storage devices comprising instructions that are executable by one or more processing devices to perform operations comprising the method of claim 1.

12. A system comprising:
one or more processing devices; and
one or more machine-readable hardware storage devices comprising instructions that are executable by the one or more processing devices to perform operations comprising the method of claim 1.

13. A method, comprising:
determining a mathematical model of the magnetic actuator which describes a change in a motor constant of the magnetic actuator as a function of the electrical drive power supplied to the magnetic actuator;
driving a magnetic actuator with a first electrical drive power as a function of a target force;
using a mathematical model to determine a change in a motor constant of the magnetic actuator due to driving the magnetic actuator with the first electrical drive power, the mathematical model describing a change in the motor constant of the magnetic actuator as a function of the electrical drive power supplied to the magnetic actuator;
determining a correction value for the first electrical drive power as a function of the change in the motor constant; and
driving the magnetic actuator with a second electrical drive power as a function of the first electrical drive power and the correction value,
wherein the method comprises using the magnetic actuator to actuate an optical element.

14. One or more machine-readable hardware storage devices comprising instructions that are executable by one or more processing devices to perform operations comprising the method of claim 13.

15. A system comprising:
one or more processing devices; and
one or more machine-readable hardware storage devices comprising instructions that are executable by the one or more processing devices to perform operations comprising the method of claim 13.

16. A drive device configured to drive a magnetic actuator to provide a mechanical force as a function of an electrical drive power, the drive device comprising:
a modeling unit configured to provide a mathematical model of the magnetic actuator which describes a change in a motor constant of the magnetic actuator as a function of the electrical drive power;
a driving unit configured to drive the magnetic actuator with a first electrical drive power as a function of a target force;
an evaluation unit configured to determine a change in the motor constant of the magnetic actuator due to driving the magnetic actuator with the first electrical drive power and as a function of the mathematical model; and
a correction unit configured to determine a correction value for the first electrical drive power as a function of the determined change in the motor constant of the magnetic actuator,
wherein the driving unit is configured to drive the magnetic actuator with a second electrical drive power as a function of the first electrical drive power and the correction value.

17. The drive device of claim 16, further comprising a detection unit configured to detect an electrical drive power supplied to the magnetic actuator, wherein the evaluation unit is configured to determine the change in the motor constant as a function of the detected electrical drive power.

18. A system, comprising:
an actuator; and
a drive device according to claim 16,
wherein the drive device is configured to drive the actuator.

19. The system of claim 18, further comprising an optical element configured to be actuated by the actuator

20. The system of claim 18, wherein the system comprises a lithography optical system.
